(19) United States
(12) Patent Application Publication
(10) Pub. No.: US 2024/0347491 A1
(43) Pub. Date: Oct. 17, 2024

(54) BUMP STRUCTURE AND MANUFACTURING METHOD THEREOF

(71) Applicant: SITRONIX TECHNOLOGY CORP., Hsinchu County (TW)

(72) Inventor: Kuo-Wei Tseng, Hsinchu County (TW)

(21) Appl. No.: 18/202,360

(22) Filed: May 26, 2023

Related U.S. Application Data
(60) Provisional application No. 63/365,342, filed on May 26, 2022.

(51) Int. Cl. H01L 23/00; H01L 23/31

(52) U.S. Cl. CPC H01L 24/13; H01L 24/11; H01L 23/3171; H01L 24/16; H01L 2224/11462; H01L 2224/1147; H01L 2224/1308; H01L 2224/13111; H01L 2224/13139; H01L 2224/13144; H01L 2224/13147; H01L 2224/16225

(57) ABSTRACT

The present application discloses a bump structure and a manufacturing method thereof. The bump structure comprises a first bump layer disposed on a chip and a second bump layer disposed on the first bump layer, and the hardness of the first and second bump layers are different, and both materials of the first and second bump layers are the same conductive material. Thus, when the chip is connected with a substrate through the bump structure and a force applied to the bump structure, it is not easily to cause that the bump structure makes a damage on the chip, and the bump structure according to the present invention is to enhance the structure characteristic and prevented from damaging.

### FIELD OF THE INVENTION

The present application is related to a bump structure and a method for manufacturing thereof, particularly a bump structure disposed on a chip and a method for manufacturing thereof.

### BACKGROUND OF THE INVENTION

In general, a bump structure is used for bonding a chip to a substrate or a carrier. For example, solar cell chips, control chips, driver chips, coding and decoding chips are bonded to the corresponding substrates or carriers and transmit signals via bump structures.

As the processes of chips become more delicate, the corresponding bumps become more delicate as well. In addition, the prices of metal materials keep increasing owing to inflation. The shrinkage of bump size has become an inevitable trend in the industry. Unfortunately, the bumps with reduced size deform more seriously under stress. In the process of disposing a chip on a substrate or a carrier, the force applied to a unit area of a bump with reduced size is greater than that of a bump with size not reduced. Consequently, the bump with reduced size deforms significantly, which might lead to damages on the devices or circuitry on the chip.

Accordingly, the present application provides a bump structure and a method for manufacturing thereof. By using bump layers with different hardness, the applied force may be reduced and avoided for chips. Then damages on chips may be prevented by eliminating force transfer. By improving the property in structure, damages on the bump structure may be avoided as well.

### SUMMARY OF THE INVENTION

An objective of the present application is to provide a bump structure and a method for manufacturing thereof. The bump structure comprises a plurality of bump layer with different hardness. Thereby, the applied force may be reduced and avoided for chips. Then damages on chips may be prevented by eliminating force transfer. By improving the property in structure, damages on the bump structure may be avoided as well.

To achieve the above objective, the present application provides a bump structure, which is disposed on a chip and comprises a first bump layer and a second bump layer. The first bump layer is disposed on the chip. The second bump layer is disposed on the first bump layer. The first bump layer and the second bump layer have different hardness. The materials of the first bump layer and the second bump layer are the same conductive material. Thereby, the force applied to the bump structure may be cancelled out. Then damages on the chip may be prevented by eliminating force transfer. By improving the property in structure, damages on the bump structure may be avoided as well.

To achieve the above objective, the present application provides a method for manufacturing bump structure applied to a bump structure disposed on a chip. The method for manufacturing bump structure comprises forming a first bump layer on the chip; and forming a second bump layer on the first bump layer; where the first bump layer and the second bump layer have different hardness; and the materials of the first bump layer and the second bump layer are the same conductive material.

### BRIEF DESCRIPTION OF DRAWINGS

FIG. 1 shows a schematic diagram of the bump structure according to the first embodiment of the present application;

FIG. 2A to FIG. 2H show schematic diagrams of the steps for manufacturing the bump structure according to the first embodiment of the present application;

FIG. 3 shows a schematic diagram of the bump structure according to the second embodiment of the present application;

FIG. 4A to FIG. 4J show schematic diagrams of the steps for manufacturing the bump structure according to the second embodiment of the present application;

FIG. 5 shows a schematic diagram of the bump structure according to the third embodiment of the present application;

FIG. 6A to FIG. 6K show schematic diagrams of the steps for manufacturing the bump structure according to the third embodiment of the present application; and

FIG. 7 shows a schematic diagram of the bump structure according to the fourth embodiment of the present application.

### DETAILED DESCRIPTION OF THE INVENTION

In order to make the structure and characteristics as well as the effectiveness of the present application to be further understood and recognized, the detailed description of the present application is provided as follows along with embodiments and accompanying figures.

In the specifications and subsequent claims, certain words are used for representing specific devices. A person having ordinary skill in the art should know that hardware manufacturers might use different nouns to call the same device. In the specifications and subsequent claims, the differences in names are not used for distinguishing devices. Instead, the differences in functions are the guidelines for distinguishing. In the whole specifications and subsequent claims, the word “comprising” is an open language and should be explained as “comprising but not limited to”. Besides, the word “couple” includes any direct and indirect electrical connection. Thereby, if the description is that a first device is coupled to a second device, it means that the first device is connected electrically to the second device directly, or the first device is connected electrically to the second device via other device or connecting means indirectly.

Given that the applied force damaging chips cannot be reduced by shrinking bumps according to the prior art, the present application provides a bump structure and the method for manufacturing thereof, which include composite bump layers with different hardness for solving the problem according to the prior art.

In the following description, various embodiments of the present application are described using figures for describing the present application in detail. Nonetheless, the concepts of the present application may be embodied by various forms. Those embodiments are not used to limit the scope and range of the present application.

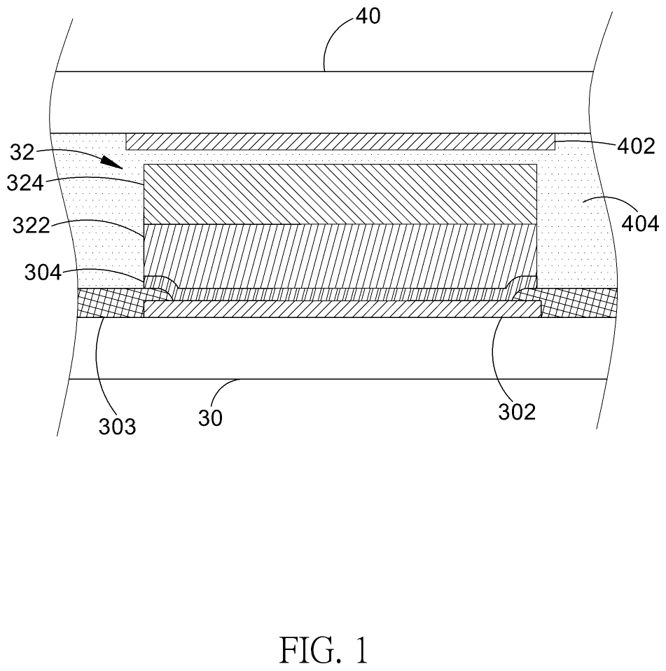

First, please refer to FIG. 1, which shows a schematic diagram of the bump structure according to the first embodiment of the present application. As shown in the figure, according to the present embodiment, a bump structure 32 is disposed on a chip 30. The bump structure 32 is used for bonding the chip 30 to a substrate 40. According to the present embodiment, a contact pad 302 is disposed on the chip 30. The bump structure 32 according to the present embodiment is disposed on the chip 30. The bump structure 32 comprises a first bump layer 322 and a second bump layer 324. The first bump layer 322 is disposed on the contact pad 302. The second bump layer 324 is disposed on the first bump layer 322. The first bump layer 322 and the second bump layer 324 of the bump structure 32 have different hardness, and thus cancelling out the force applied to the bump structure 32. For example, the hardness of the second bump layer 324 is greater than the hardness of the first bump layer 322. The first bump layer 322 with lower harness may act to buffer the applied force. When a force is applied to the bump structure 32, the second bump layer 324 with higher hardness first receives the force for avoiding excessive deformation of the bump structure 32.

To elaborate, according to the present embodiment, the first bump layer 322 is located on a first metal layer 304. The first metal layer 304 is located between the first bump layer 322 and the contact pad 302. In other words, the first metal layer 304 is located on the chip 30. The first metal layer 304 may be an under bump metallization (UBM) layer, which provides signal connection function. Thereby, disposing the first bump layer 322 on the UBM layer is equivalent to disposing the first bump layer 322 on the contact pad 302. Furthermore, a passivation layer 303 is disposed on the chip 30. The passivation layer 303 is disposed on the contact pad 302. Since the passivation layer 303 according to the present embodiment has an opening, the contact pad 302 will be exposed. In other words, the passivation layer 303 surrounds the contact pad 33 and is disposed on the chip 30. The contact pad 302, the first metal layer 304, and the first bump layer 322 correspond to the opening of the passivation layer 303.

When the chip 30 is bonded to the substrate 40 via the bump structure 32, a connection member 402 and a medium layer 404 are further included between the chip 30 and the substrate 40. The medium layer 404 is disposed between the second bump layer 324 and the connection member 402 and stuffed between the chip 30 and the substrate 40. The connection member 402 is disposed on the substrate 40. The medium layer 404 includes a plurality of conductive particles (not shown in the figure). For example, an anisotropic conductive film (ACF) includes a plurality of conductive particles. Thereby, the connection member 402 and the medium layer 404 are disposed on the substrate 40 for bonding the chip 30 to the substrate 40. Furthermore, by squeezing the medium layer 404, the bump structure 32 may be coupled to the chip 30 and hence establishing signal transmission between the chip 30 and the substrate 40.

In the following, the flow of manufacturing the bump structure 32 according to the first embodiment will be described in detail.

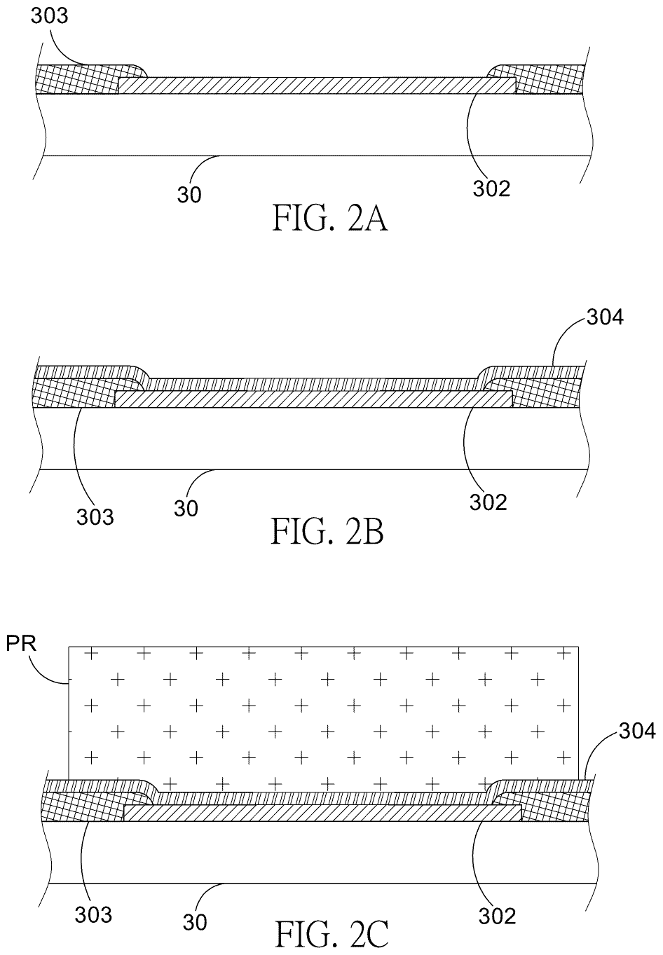

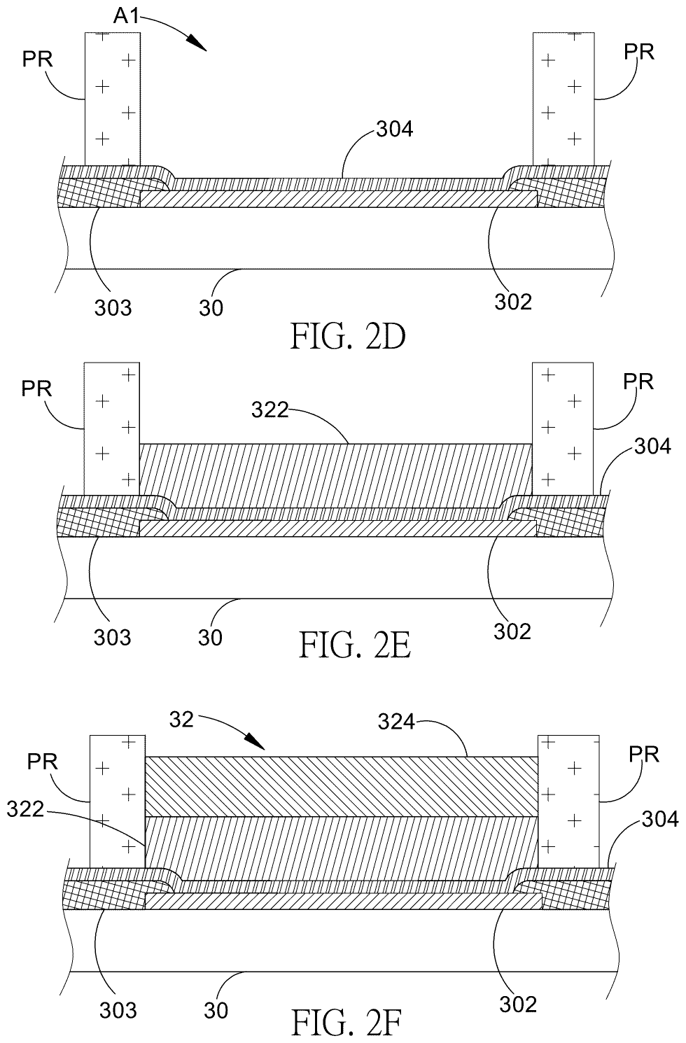

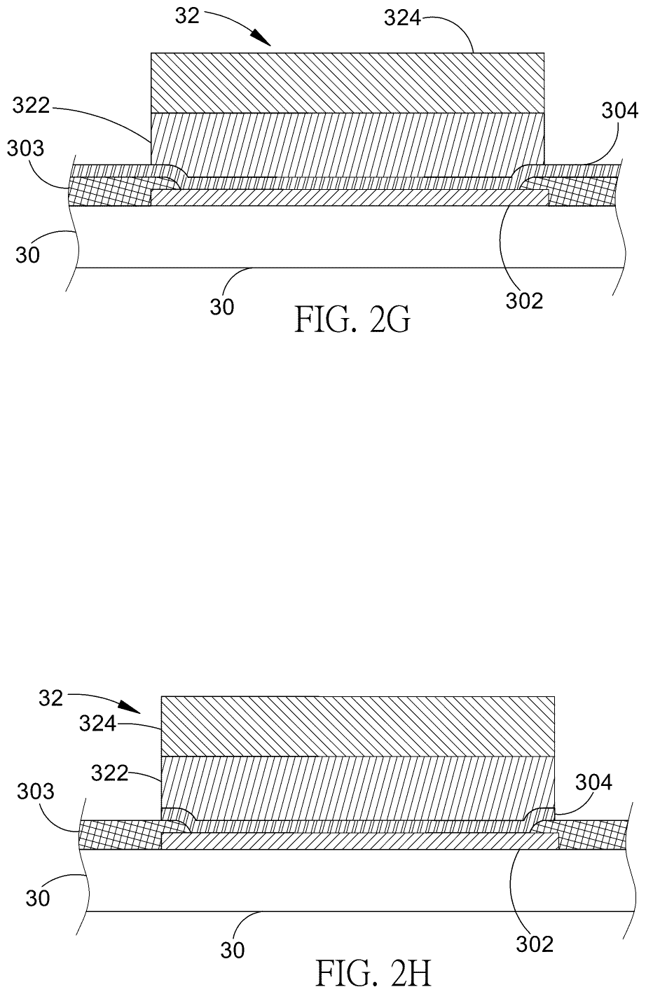

Please refer to FIG. 2A to FIG. 2H, which show schematic diagrams of the steps for manufacturing the bump structure according to the first embodiment of the present application. As shown in the figures, the method for manufacturing bump structure according to the present application is to provide the bump structure 32 for disposing on the contact pad 302 of the chip 30. To elaborate, as shown in FIG. 2A, provide the chip 30 with the contact pad 302 thereon. The contact pad 302 is surrounded by the passivation layer 303. The material of the contact pad 302 is selected from a metal material such as aluminum. Then, as shown in FIG. 2B, form the first metal layer 304 on the contact pad 302 and the passivation layer 303 and covering them. The first metal layer 304 includes a single layer structure or a composite structure formed by multiple sublayers with different materials. The layers of the composite structure are selected from the group comprising nickel (Ni) layer, titanium (Ti) layer, tungsten titanium (TiW) layer, palladium (Pd) layer, gold (Au) layer, and silver (Ag) layer. The first metal layer 304 according to the present embodiment is formed on the contact pad 302 and the passivation layer 303 by physical vapor deposition (PVD), chemical vapor deposition (CVD), or sputtering process. Next, as shown in FIG. 2C, a photoresist layer PR is formed on the first metal layer 304. The material of the photoresist layer PR is just the general photoresist material including positive and negative photoresists.

As shown in FIG. 2D, a portion of the photoresist layer PR is stripped according to the location of the bump structure 32 and forming a first accommodating space A1. Next, as shown in FIG. 2E, form the first bump layer 322 on the first metal layer 304. Since the first metal layer 304 is used for signal transmission, it is equivalent to forming the first bump layer 322 on the contact pad 302. As shown in FIG. 2F, form the second bump layer 324 on the first bump layer 322. Furthermore, as shown in FIG. 2G, strip the photoresist layer PR by, for example, using an etching solution. Next, as shown in FIG. 2H, remove the first metal layer 304 outside the coverage of the bump structure 32. For example, etch the first metal layer 304 except the coverage region below the first bump layer 322 and hence exposing the passivation layer 303.

In the above steps shown in FIG. 2E to FIG. 2F, the first bump layer 322 and the second bump layer 324 may be formed sequentially on the chip 30 by PVD, plating, or CVD process. After the step shown in FIG. 2G, the first bump layer 322 and the second bump layer 324 may be annealed for reorganizing the grains therein and eliminating internal stress.

In the plating process, different currents may be set in the same plating tank (not shown in figures) for forming the first bump layer 322 and the second bump layer 324 with different grain sizes. For example, a first current is used in plating for forming the first bump layer 322 and a second current is used in plating for forming the second bump layer 324. The second current is greater than the first current. Since a smaller current in plating resulting in greater grain size, the grain size of the first bump layer 322 is greater than the grain size of the second bump layer 324. Besides, the hardness is higher for smaller grain size. Thereby, the hardness of the second bump layer 324 is greater than the hardness of the first bump layer 322. In addition, the materials of the first and second bump layers 322, 324 may be the same conductive material, for example, gold, silver, copper, or tin. Moreover, different plating solutions with different characteristics may be used to plate the same conductive material for forming the first bump payer 322 and the second bump layer 324. For example, the plating solution may be a cyanide or a non-cyanide. By adopting the non-cyanide, the grain size will be smaller and the hardness will be higher. On the contrary, if the cyanide is adopted, the grain size will be greater and the hardness will be smaller.

Furthermore, please refer to FIG. 2E again. After forming the first bump layer 322, a heat treatment may be performed for annealing and baking the first bump layer 322. In addition, please refer to FIG. 2F again. After forming the second bump layer 324, the heat treatment may be performed for annealing and baking the first bump layer 322 and the second bump layer 324. Since the first bump layer 322 experiences longer heat treatment, its grain size will grow larger and hence leading to smaller hardness than the second bump layer 324. Besides, please refer to FIG. 2E and FIG. 2F again, plating solutions with different temperatures may be used forming the first bump layer 322 and the second bump layer 324. If the temperature of the plating solution is higher, the grain size of the formed bump layer will be larger. Thereby, the first bump layer 322 and the second bump layer 324 with different hardness may be formed. For example, the temperature of the plating solution for forming the first bump layer 322 is higher than the temperature of the plating solution for forming the second bump layer 324. Consequently, the hardness of the first bump layer 322 will be smaller than the hardness of the second bump layer 324.

In addition, the materials of the first bump layer 322 and the second bump layer 324 are the same conductive material. Thereby, the metal affinity between the first bump layer 322 and the second bump layer 324 may be increased. For example, the materials of the first bump layer 322 and the second bump layer 324 are selected from the group consisting of gold, silver, copper, and tin and thus increasing the metal affinity between the first bump layer 322 and the second bump layer 324. Accordingly, when the shear stress is applied to the bump structure 32, it will not be damaged by the shear stress due to inferior metal affinity.

Besides, because the hardness of the second bump layer 324 is greater than the hardness of the first bump layer 322, the second bump layer 324 may reduce the deformation caused by the force generated during the process when the chip 30 is bonded to the substrate 40. Furthermore, the first bump layer 322 is used for providing the damping effect for buffering the applied force.

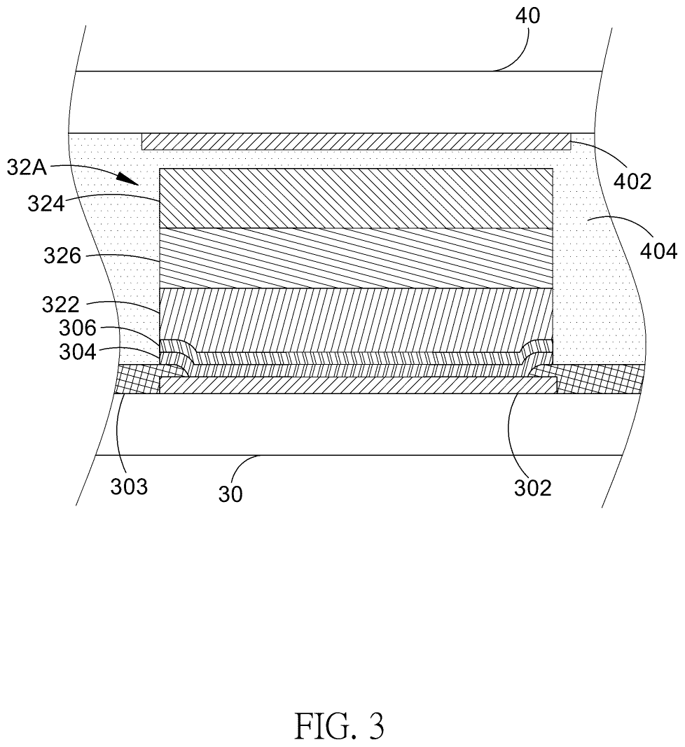

According to the above embodiment, the bump structure 32 according to the present application comprises the first bump layer 322 and the second bump layer 324 formed on the contact pad 302. In the following, the bump structure 32A according to the present application will be further disclosed. The bump structure 32A further comprises a first bump buffer layer 326, as shown in FIG. 3.

To elaborate, please refer to FIG. 3, which shows a schematic diagram of the bump structure according to the second embodiment of the present application. The difference between FIG. 1 and FIG. 3 is that, in FIG. 3, a second metal layer 306 and a first bump buffer layer 326 are further disposed. The second metal layer 306 is disposed between the first metal layer 304 and the first bump layer 322. The first bump buffer layer 326 is disposed between the first bump layer 322 and the second bump layer 324. In addition, the hardness of the first bump layer 322 is smaller than the hardness of the first bump buffer layer 306; the hardness of the first bump buffer layer 326 is smaller than the hardness of the second bump layer 324. Thereby, the bump structure 32A according to the present embodiment may provide better buffering effect on the applied force. In other words, when the first bump buffer layer 326 cannot cancel out all the applied force, the remaining applied force will be transferred to the first bump layer 322 for final buffering. According to the above description, at least one metal layer is located between the first bump layer 322 and the contact pad 302. According to the requirement, a plurality of metal layer may be further disposed. Besides, at least one bump buffer layer may be disposed between the first bump layer 322 and the second bump layer 324 for increasing buffering effect.

In the following, the flow of manufacturing the bump structure 32A according to the second embodiment will be illustrated.

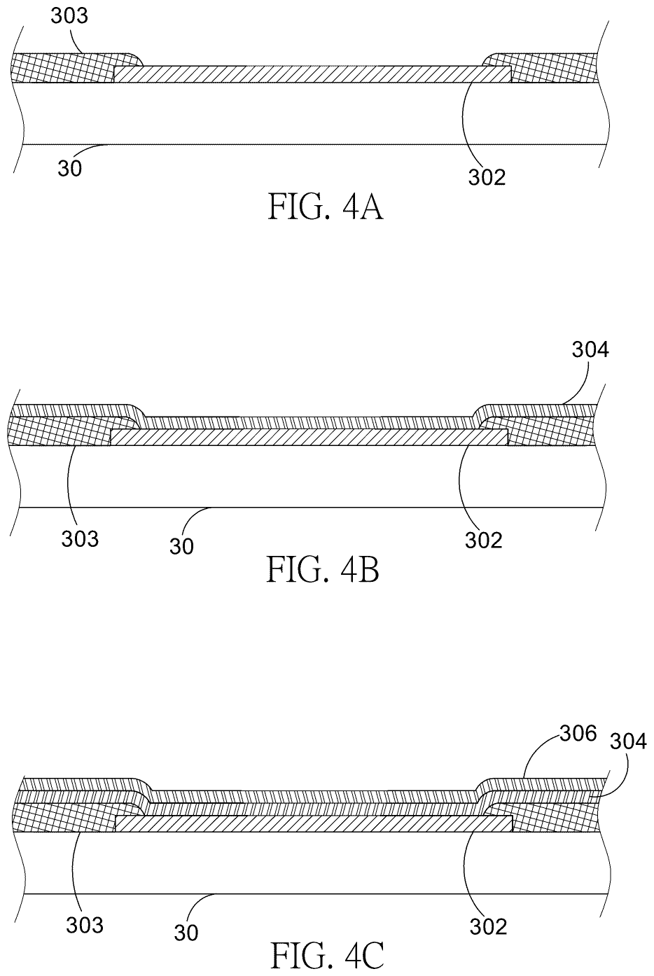

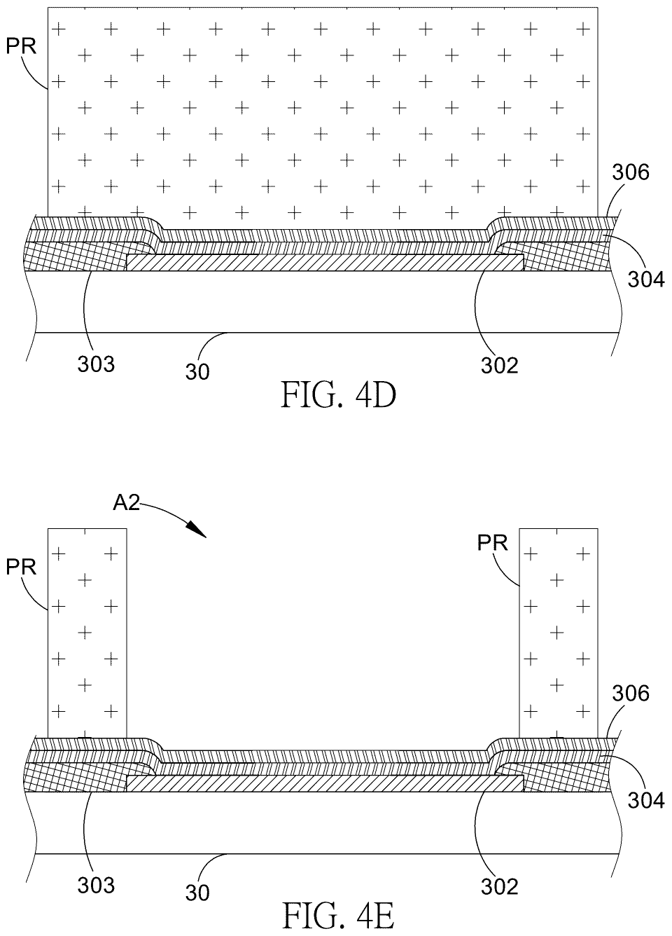

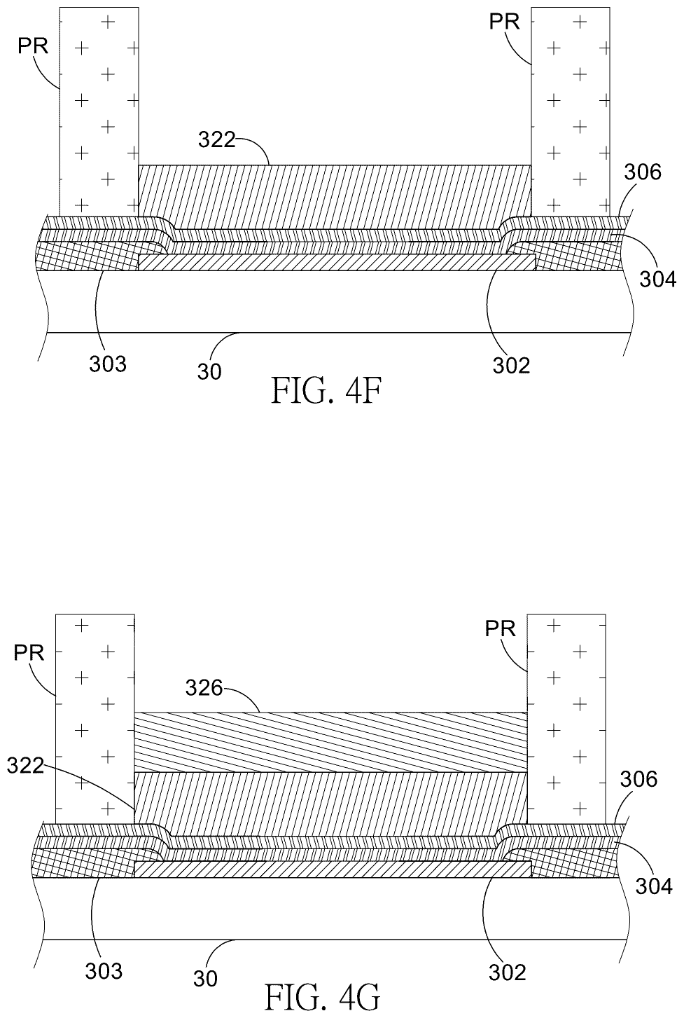

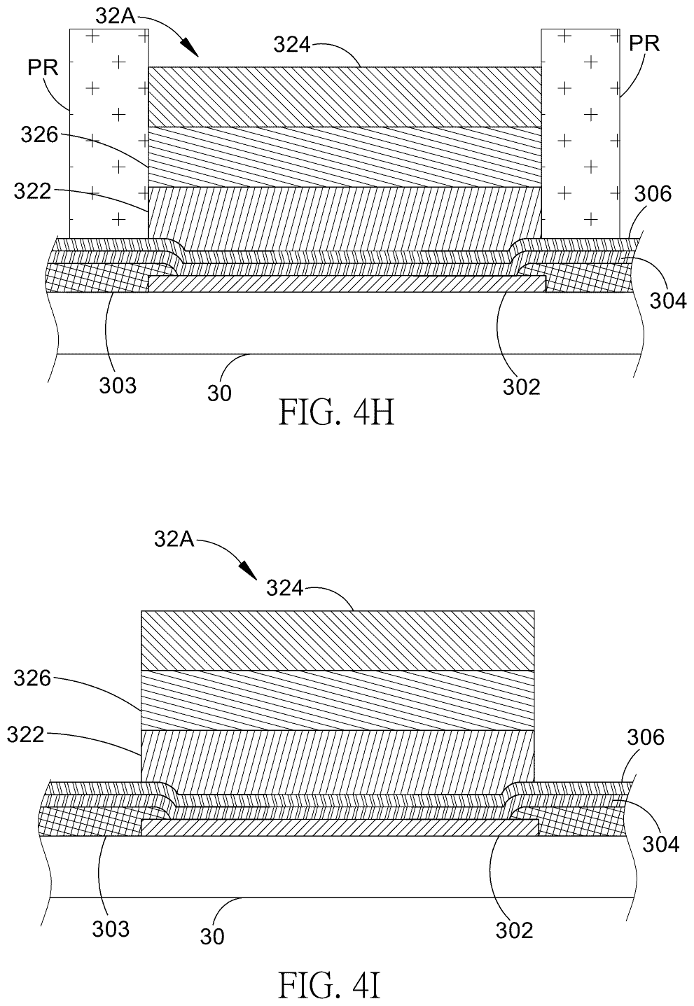

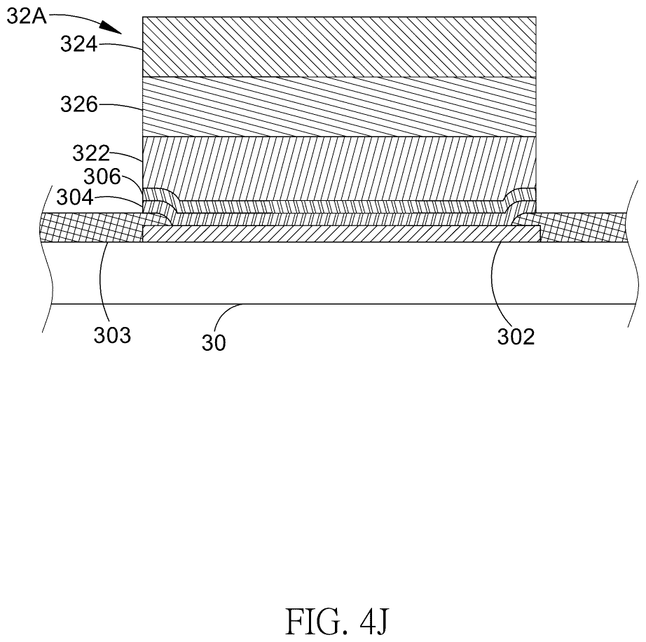

The steps in FIG. 4A and FIG. 4B according to the present embodiment are identical to those in FIG. 2A and FIG. 2B according to the first embodiment. Thereby, the chip 30 and the first metal layer 304 will not be described again. Next, as shown in FIG. 4C, compared to the first embodiment, the present embodiment further comprises a second metal layer 306 disposed on the first metal layer 304 so that the first bump layer 322 may be formed on the second metal layer 306. The material of the second metal layer 306 includes gold, silver, or alloys. According to the present embodiment, the first metal layer 304 and the second metal layer 306 may be formed by PVD or CVD on the contact pad 302 and the passivation layer 303.

Moreover, as shown in FIG. 4D, form the photoresist layer PR on the second metal layer 306. FIG. 4D and FIG. 4E are identical to FIG. 2C and FIG. 2D according to the first embodiment. Hence, the details will not be repeated. The photoresist layer PR forms a second accommodating space A2. Next, as shown in FIG. 4F, form the first bump layer 322 in the second accommodating space A2 and on the second metal layer 306. It is equivalent to form the first bump layer 322 on the contact pad 302. As shown in FIG. 4G, further form the first bump buffer layer 326 on the first bump layer 322. Then, as shown in FIG. 4H, form the second bump buffer layer 324 on the first bump buffer layer 326. As shown in FIG. 4I, strip the photoresist layer PR and hence exposing the second metal layer 306. Next, as shown in FIG. 4J, remove the first metal layer 304 and the second metal layer 306 not covered by the first bump layer 322. For example, etch the first metal layer 304 and the second metal layer 306 not covered by the first bump layer 322. Then perform heat treatment on the first bump layer 322, the second bump layer 324, and the first bump buffer layer 326 for eliminating internal stress.

According to the above description, compared to FIG. 2A to FIG. 2H, FIG. 4A to FIG. 4J further include the first bump buffer layer 326 and the second metal layer 306. The materials of the first bump layer 322, the second bump layer 324, and the first bump buffer layer 326 are the same conductive material. The hardness of the first bump buffer layer 326 is different from the hardness of the first bump layer 322 and the second bump layer 324. For example, the hardness is step decreasing from top down. The hardness of the second bump layer 324 is 90 HV; the hardness of the first bump buffer layer 326 is 70 HV; and the hardness of the first bump layer 322 is 55 HV.

Please refer to FIG. 4F to FIG. 4H again. According to the present application, in addition to the step shown in FIG. 4J, heat treatments may be performed in the steps for forming the first bump layer 322, the first bump buffer layer 326, and the second bump layer 324. As shown in FIG. 4F, after forming the first bump layer 322, the heat treatment is performed at a first temperature for annealing and baking the first bump layer 322. As shown in FIG. 4G, after forming the first bump buffer layer 326, the heat treatment is performed at a second temperature for annealing and baking the first bump layer 322 and the first bump buffer layer 326. As shown in FIG. 4H, after forming the second bump layer 324, the heat treatment is performed at a third temperature for annealing and baking the first bump layer 322 and the first bump buffer layer 326, and the second bump layer 324. The first bump layer 322 and the first bump buffer layer 326, and the second bump layer 324 may be formed by PVD, plating, or CVD process on the contact pad 302, and be annealed and baked at the first, second, and third temperatures, respectively. The first, second, and third temperatures may be the same temperature or different temperatures. Thereby, the hardness of the first bump buffer layer 326 is different from the hardness of the first bump layer 322 and the second bump layer 324. As described above, plating solutions with different currents, different temperatures, or different characteristics may be adopted for performing the plating process for forming the first bump layer 322 and the first bump buffer layer 326, and the second bump layer 324 with different hardness.

The above description discloses a single bump buffer layer. According to the present application, a plurality of bump buffer layers may be further included, as described in the following for two bump buffer layers 326, 328.

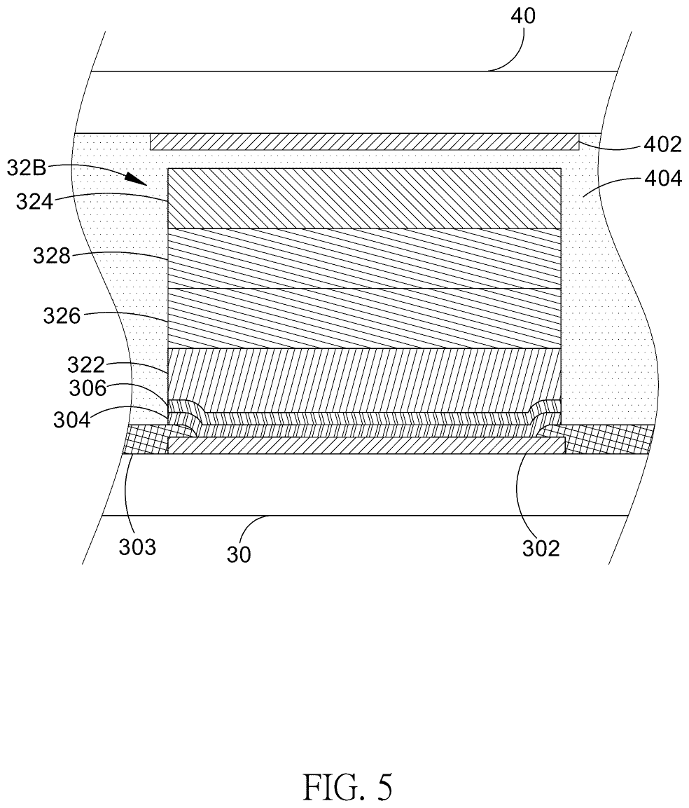

Please refer to FIG. 5, which shows a schematic diagram of the bump structure according to the third embodiment of the present application. The difference between FIG. 3 and FIG. 5 is that FIG. 5 further includes a second bump buffer layer 328 disposed between the first bump buffer layer 326 and the second bump layer 324. In addition, according to the present embodiment, the hardness decreases from top down. The second bump layer 324 has the highest hardness while the first bump layer 322 the lowest. Thereby, the bump structure 32B according to the present embodiment may provide superior buffering effect via the second bump buffer layer 326. In other words, the first bump buffer layer 326 and the second bump buffer layer 328 may buffer and diminish the applied force. If there is still remaining applied force, it will be transferred to the first bump layer 322. Since the hardness of the first bump layer 322 is the lowest, the remaining applied force may be eliminated, preventing it from transferring to the chip 30. According to the above description, at least one bump buffer layer may be disposed between the first bump layer 322 and the second bump layer 324. Furthermore, according to the requirement, a plurality of bump buffer layers may be disposed for giving superior buffering effect. In addition, the first buffer layer 322, the second buffer layer 324, the first bump buffer layer 326, and the second buffer layer 328 adopt the same conductive material for enabling good affinity of the bump structure 32B.

Moreover, according to the third embodiment as described above, since the hardness of the first bump buffer layer 326 is smaller than the hardness of the second bump buffer layer 328, the hardness of the plurality of bump buffer layers will decrease stepwise while approaching the first bump layer 322. The hardness of the bump buffer layer (like the second bump buffer layer 328 as described above) away from the first bump layer 322 is greater than the hardness of the bump buffer layer (like the first bump buffer layer 326) close to the first bump layer 322.

In the following, the method for manufacturing the bump structure 32B will be illustrated.

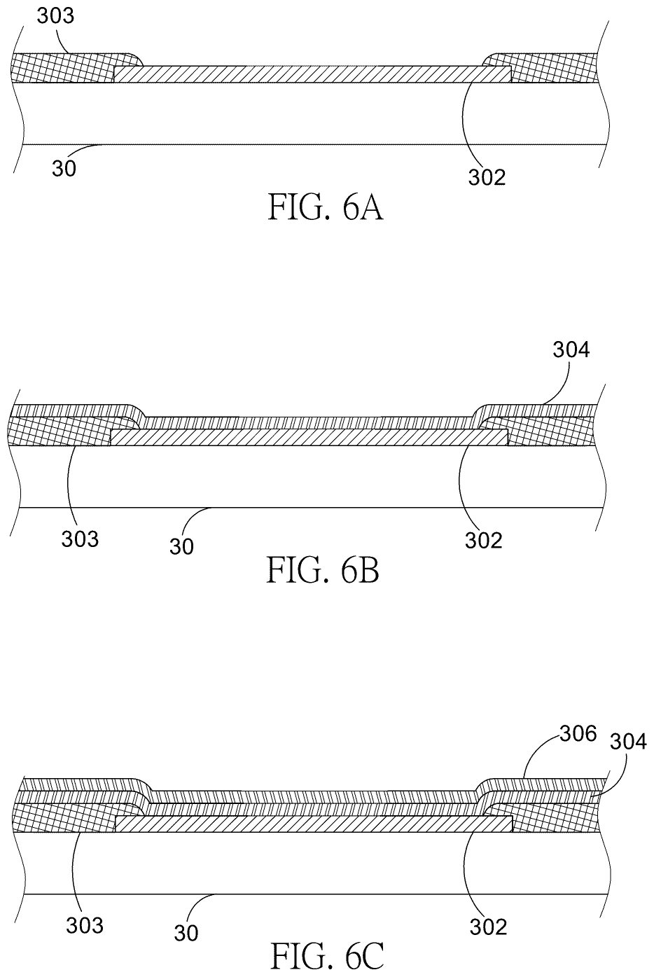

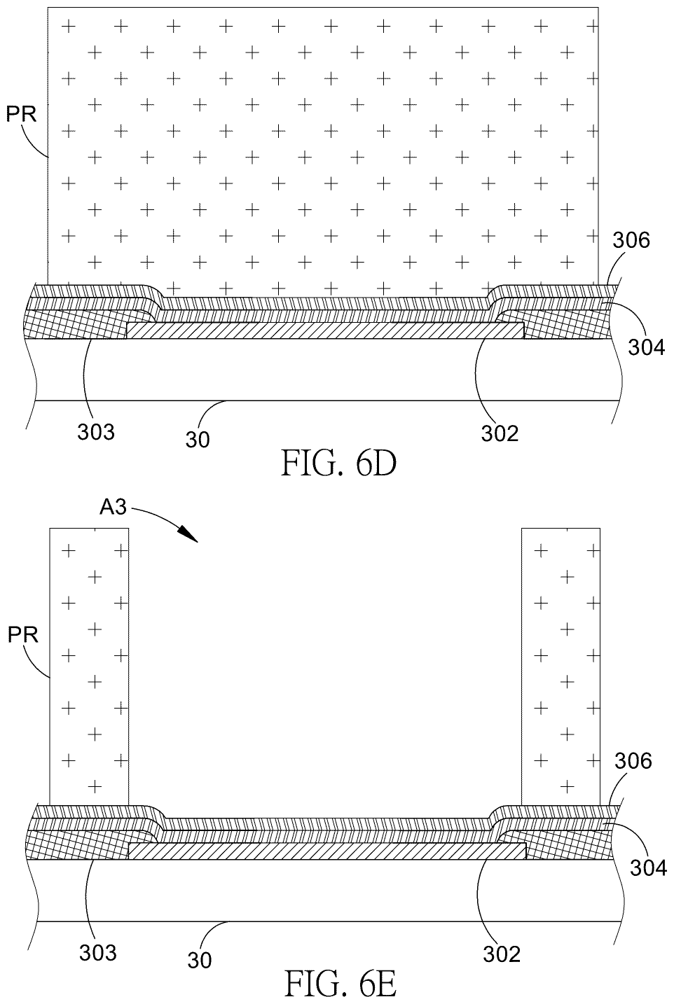

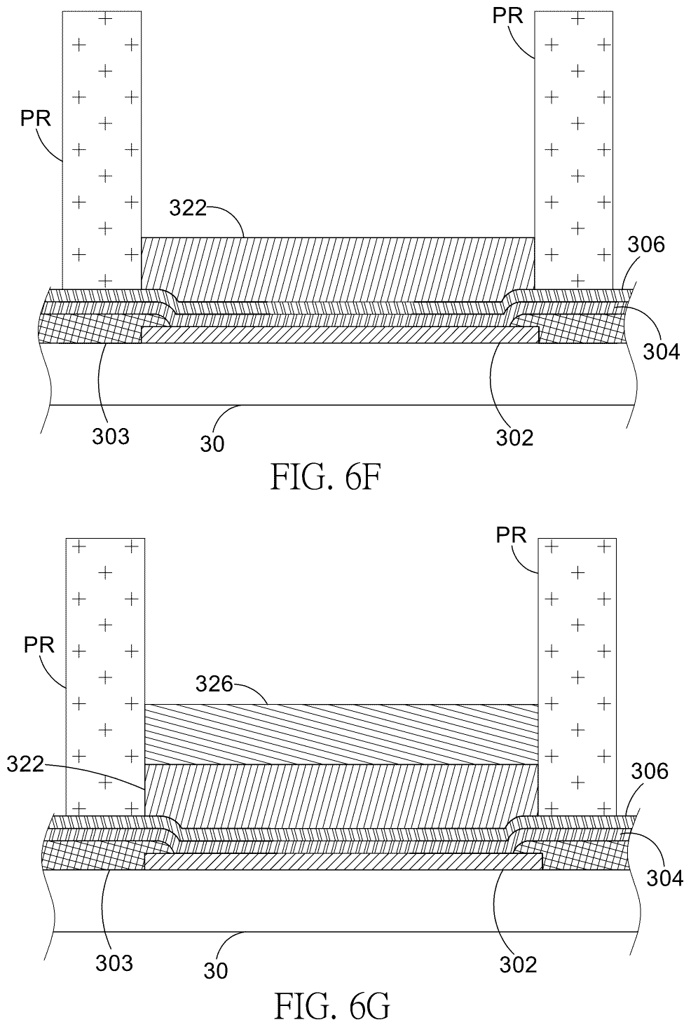

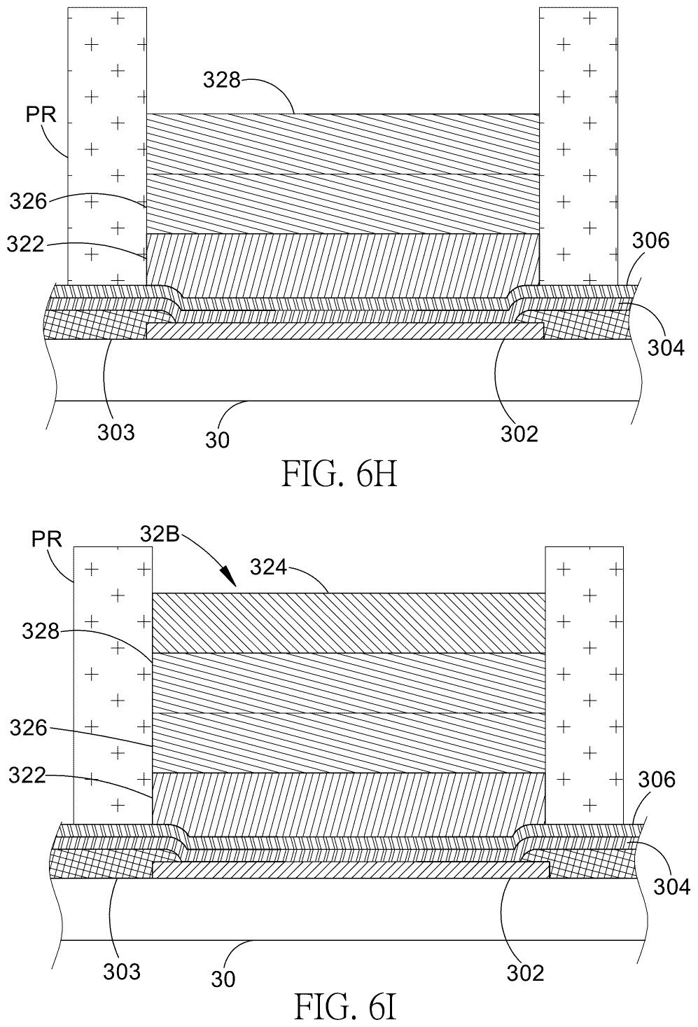

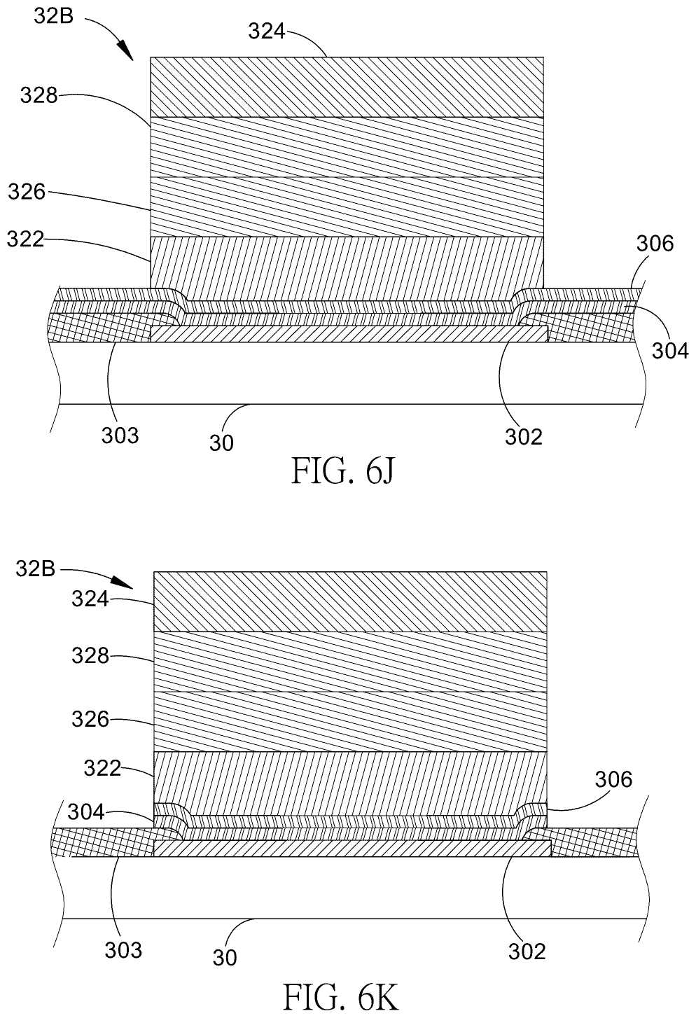

FIGS. 6A to 6G are identical to FIGS. 4A to 4G. Hence, the details will not be repeated. As shown in FIG. 6H, for the second bump buffer layer 328 on the first bump buffer layer 326. Then, as shown in FIG. 6I, form the second bump layer 324 on the second bump buffer layer 328. FIGS. 6J to 6K are identical to FIGS. 4I to 4J. The difference is that, in FIG. 6K, after removing the first metal layer 304 and the second metal layer 306 and performing heat treatment on the first bump layer 322, the first bump buffer layer 326, and the second bump layer 324, the heat treatment is applied to the second bump buffer layer 328 concurrently for eliminating internal stress. The details will not be repeated.

Furthermore, please refer to FIGS. 6F to 61 again. After the steps of forming the first bump layer 322, the first bump buffer layer 326, the second bump buffer layer 328, and the second bump layer 324, heat treatments may be performed. As shown in FIG. 6F, after forming the first bump layer 322, a heat treatment is performed for annealing and baking the first bump layer 322. Next, as shown in FIG. 6G, after forming the first bump buffer layer 326, anneal and bake the first bump layer 322 and the first bump buffer layer 326. Then, as shown in FIG. 6H, after forming the second bump buffer layer 328, anneal and bake the first bump layer 322 and the first bump buffer layer 326, and the second bump buffer layer 328. Next, as shown in FIG. 6I, after forming the second bump layer 324, anneal and bake the first bump layer 322 and the first bump buffer layer 326, the second bump buffer layer 328, and the second bump layer 324. Since the first bump layer 322 is baked for the longest time, its hardness will be smaller than the first bump buffer layer 326, the second bump buffer layer 328, and the second bump layer 324. The second bump layer 324 is baked for the shortest time. Thereby, its hardness will be greater than the first bump layer 322, the first bump buffer layer 326, and the second bump buffer layer 328. Besides, the baking time of the second bump buffer layer 328 is shorter than the baking time of the first bump buffer layer 326. Thereby, the hardness of the second bump buffer layer 328 will be greater than the hardness of the first bump buffer layer 326. As described above, plating solutions with different currents, different temperatures, or different characteristics may be adopted for performing the plating process for forming the first bump layer 322 and the first bump buffer layer 326, the second bump buffer layer 328, and the second bump layer 324 with different hardness.

According to the above embodiments, the bump structures 32, 32A, 32B are disposed at the opening of the passivation layer 303. Since the first metal layer 304 contacts the contact pad 302, the contact pad 302 may be connected electrically to the bump structures 32, 32A, 32B via the first metal layer 304 or the second metal layer 306. Furthermore, the present application may be applied to dummy bumps for dispersing the force generated while bonding the chip 30 to the substrate 40.

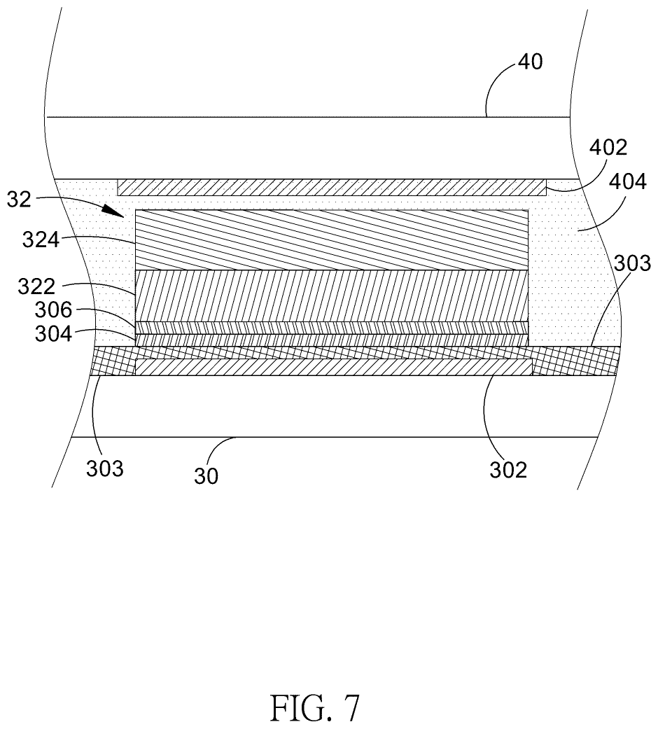

Please refer to FIG. 7, which shows a schematic diagram of the bump structure according to the fourth embodiment of the present application. The difference between FIG. 1 and FIG. 7 is that the passivation layer 303 in FIG. 7 does not include the opening and thereby the contact pad 302 is not exposed. According to the present embodiment, the bump structure may disperse the force generated while bonding the chip 30 to the substrate 40. In addition to the bump structure for transmitting signals, the applied force will also be applied to the dummy bump structure according to the present embodiment for distributing the applied force uniformly and avoiding damages on the bump structures and chips.

To sum up, the present application provides the bump structure and the method for manufacturing thereof. The present application provides the first bump layer and the second bump layer with different hardness to equip the bump structure with buffering function. By further including the bump buffer layers, superior buffering function may be provided for achieving excellent cancellation effect on the applied force. Thereby, when a chip is bonded to a substrate via the bond structure according to the present application, the chip will not be damaged easily. In addition, the structure characteristics of the bump structure itself is enhanced as well for preventing it from damages.

Accordingly, the present application conforms to the legal requirements owing to its novelty, nonobviousness, and utility. However, the foregoing description is only embodiments of the present application, not used to limit the scope and range of the present application. Those equivalent changes or modifications made according to the shape, structure, feature, or spirit described in the claims of the present application are included in the appended claims of the present application.

1. A bump structure, disposed on a chip, comprising:
a first bump layer, disposed on said chip; and
a second bump layer, disposed on said first bump layer;
wherein the materials of said first bump layer and said second bump layer are the same conductive material; and the hardness of said first bump layer is different from the hardness of said second bump layer.

2. The bump structure of claim 1, further comprising at least one bump buffer layer disposed between said first bump layer and said second bump layer; wherein the materials of said first bump layer, said second bump layer, and said at least one bump buffer layer are the same conductive material; and the hardness of said at least one bump buffer layer is different from the hardness of said first bump layer and said second bump layer.

3. The bump structure of claim 2, wherein the hardness of said first bump layer is smaller than the hardness of said at least one bump buffer layer; and the hardness of said at least one bump buffer layer is smaller than the hardness of said second bump layer.

4. The bump structure of claim 3, wherein said at least one bump buffer layer includes a plurality of bump buffer layers; the hardness of said first bump layer is smaller than the hardness of said bump buffer layers; the hardness of said bump buffer layers is smaller than the hardness of said second bump layer; the hardness of said bump buffer layers decreases stepwise while approaching said first bump layer; and the hardness of said bump buffer layer away from said first bump layer is greater than the hardness of said bump buffer layer close to said first bump layer.

5. The bump structure of claim 1, wherein the hardness of said first bump layer is smaller than the hardness of said second bump layer.

6. The bump structure of claim 1, wherein said first bump layer is located on at least one metal layer; and said at least one metal layer is located of said chip.

7. The bump structure of claim 1, wherein said first bump layer is located on a passivation layer; said passivation layer is located on a contact pad; and said contact pad is located on said chip and contacting said chip.

8. The bump structure of claim 7, wherein said first bump layer is located on at least one metal layer; and said at least one metal layer is located on said passivation layer.

9. The bump structure of claim 7, wherein said passivation layer has an opening; and said contact pad and said first bump layer correspond to said opening.

10. The bump structure of claim 9, wherein said first bump layer is located on at least one metal layer; said at least one metal layer corresponds to said opening; and said at least one metal layer is located on and contacts said contact pad.

11. A method for manufacturing a bump structure, applied to disposing said bump structure on a chip, comprising:
forming a first bump layer on said chip; and
forming a second bump layer on said first bump layer;
wherein the materials of said first bump layer and said second bump layer are the same conductive material; and the hardness of said first bump layer is different from the hardness of said second bump layer.

12. The method for manufacturing bump structure of claim 11, further comprising: forming at least one bump buffer layer on said first bump layer; wherein said second bump layer is formed on said at least one bump buffer layer; the materials of said first bump layer, said second bump layer, and said at least one bump buffer layer are the same conductive material; and the hardness of said at least one bump buffer layer is different from the hardness of said first bump layer and said second bump layer.

13. The method for manufacturing bump structure of claim 12, wherein the hardness of said first bump layer is smaller than the hardness of said at least one bump buffer layer; and the hardness of said at least one bump buffer layer is smaller than the hardness of said second bump layer.

14. The method for manufacturing bump structure of claim 13, wherein said at least one bump buffer layer includes a plurality of bump buffer layers; the hardness of said first bump layer is smaller than the hardness of said bump buffer layers; the hardness of said bump buffer layers is smaller than the hardness of said second bump layer; the hardness of said bump buffer layers decreases stepwise while approaching said first bump layer; and the hardness of said bump buffer layer away from said first bump layer is greater than the hardness of said bump buffer layer close to said first bump layer.

15. The method for manufacturing bump structure of claim 12, further comprising:
annealing said first bump layer after forming said first bump layer;
annealing said first bump layer and said at least one bump buffer layer after forming said at least one bump buffer layer; and
annealing said first bump layer, said at least one bump buffer layer, and said second bump layer after forming said second bump layer.

16. The method for manufacturing bump structure of claim 11, wherein the hardness of said first bump layer is smaller than the hardness of said second bump layer.

17. The method for manufacturing bump structure of claim 11, further comprising:
annealing said first bump layer after forming said first bump layer; and
annealing said first bump layer and said second bump layer after forming said second bump layer.

18. The method for manufacturing bump structure of claim 11, further comprising: forming a passivation layer on said chip; wherein said first bump layer is formed on said passivation layer.

19. The method for manufacturing bump structure of claim 18, further comprising: forming at least one metal layer on said passivation layer; wherein said first bump layer is formed on said at least one metal layer.

20. The method for manufacturing bump structure of claim 11, wherein forming said first bump layer and said second bump layer adopt plating process with different current conditions.

21. The method for manufacturing bump structure of claim 11, wherein forming said first bump layer and said second bump layer adopt plating process with a plating solution at different temperatures.

22. The method for manufacturing bump structure of claim 11, wherein forming said first bump layer and said second bump layer adopt plating process with different plating solutions.
